(19) United States
(12) Patent Application Publication
(10) Pub. No.: US 2002/0177047 A1
(43) Pub. Date: Nov. 28, 2002

(54) Photomask and method for manufacturing the same

(76) Inventor: Chul-hong Park, Yongin-city (KR)

Correspondence Address: THE LAW OFFICES OF EUGENE M. LEE, PLLC, 1101 WILSON BOULEVARD, SUITE 2000, ARLINGTON, VA, 22209, US

(21) Appl. No.: 10/035,308

(22) Filed: Jan. 4, 2002

(30) Foreign Application Priority Data
May 23, 2001 (KR) 01-28484

(51) Int. Cl. G03F 9/00; G03C 5/00; G03G 16/00

(52) U.S. Cl. 430/5; 430/322; 430/324; 430/394

(57) ABSTRACT

A photomask having a trim mask, which includes a chrome mask placed at a position corresponding to a gate region and a phase shift mask placed at a position corresponding to a field poly region, and a method for manufacturing the same. In the case of using the trim mask, the margin of focal depth in the gate pattern region may be obtained, and simultaneously, the margin of focal depth in the field poly pattern region may be obtained. As a result, it is possible to reduce the length of a field poly pattern as well as the length of a gate pattern, and thus it is possible to reduce the size of a chip using the trim mask of the present invention. Moreover, the present invention facilitates performing optical proximity correction on the gate pattern region.

### BACKGROUND OF THE INVENTION

1. Field of the Invention

The present invention relates to a photomask used to manufacture a semiconductor device. More particularly, the present invention relates to a photomask including a trim mask and a method for manufacturing the same.

2. Description of the Related Art

A photolithographical process for embodying fine circuits on a wafer represents an important part in the manufacture of semiconductor devices. Accordingly, the quality of the photolithographical process greatly affects the quality of a whole semiconductor device including the semiconductor chips as well as the productivity of the semiconductor chips. Photomasks are patterned masks used in such a photolithographical process. Chrome binary masks are one kind of photomask and are a chrome patterned quartz substrate. As the integration density of semiconductor devices increases, chrome binary masks are required to have a higher resolution. The chrome binary masks, however, have a limit in satisfying the demand because of a light diffraction phenomenon. As an alternative to the chrome binary masks, phase shift masks have been developed. The phase shift masks contain a phase shifting material, which is selectively formed on a quartz substrate and can transmit light. Although the phase shift masks are used with conventional exposure equipment, which has been conventionally employed with the chrome binary masks, the phase shift masks, unlike the chrome binary masks, can enhance the resolution and focal depth of phase. Among the various kinds of phase shift masks, halftone phase shift masks, which use a halftone material instead of chrome patterns for controlling the transmittance and phase of light, are the most widely used.

In the meantime, as the integration density of semiconductor devices increases, more and more gates having a reduced length are manufactured using a trim mask as well as a phase shift mask. A trim mask indicates a mask for blocking transmission of particular light passing through a phase shift mask from reaching a wafer. Herein, a mask complementary to or opposite to the trim mask is referred to as a shifter.

A conventional procedure of forming a gate having a reduced length on a wafer using a trim mask will be described with reference to FIG. 1. When forming a chip pattern 10 including an active region pattern 13, a gate 15, a predetermined portion of which overlies the active region pattern 13, and a field poly 17 connected to the gate 15 on a wafer 11, a trim mask 20 and a shifter 26 are used. The trim mask 20 includes a transparent layer 21 and an opaque pattern 23 formed of chrome, and the shifter 26 includes an opaque layer 25 formed of chrome, transparent layers 27a and 27c with a 0° phase, a transparent layer 27b with 180° phase, and chrome opaque layers 29a and 29b placed between the transparent layers 27a, 27b, and 27c, respectively.

The shifter 26 is exposed to light and then a shifter image 36 is formed through the shifter 26 on the wafer 11. Only a portion of photoresist formed on the wafer 11, which is placed under the transparent layers 27a and 27c with a 0° phase and the transparent layer 27b with a 180° phase, is exposed while other portions of the photoresist are not exposed. As a result, exposed regions 37a, 37b, and 37c and non-exposed regions 35, 39a, and 39b are formed. The non-exposed regions 39a and 39b control (or affect) the length of the gate 15. The non-exposed regions 39a and 39b may be formed without the chrome opaque layers 29a and 29b because destructive interference occurs at a boundary between the transparent layers 27a and 27c with 0° phase and the transparent layers 27b with 1800 phase and thus a dark line along which light cannot be detected, is formed.

Light is illuminated on the trim mask 20, and then a trim image 30 is formed on the wafer 11. The trim image 30 is comprised of an exposed region 31 and a non-exposed region 33

In order to form the gate 15 and field poly 17 of the chip pattern 10, a predetermined portion of the non-exposed region 33 of the trim image 30 must be converted into an exposed region through the shifter image 36. For this, the trim mask 20 and the shifter 26 are laid on top of each other above the wafer 11 when exposing the wafer 11 to light. Then, a chip pattern image 40 is formed.

Non-exposed regions 43a, 43b, and 45 of the chip pattern image 40 include a gate pattern used to form the gate 15 and the field poly pattern 45 used to form the field poly 17. The field poly 17 indicates a poly pattern, which is formed outside the region on which the gate 15 is formed. In other words, the non-exposed regions 43a and 43b include a predetermined portion of the field poly 17, which is made to be in contact with the gate pattern in consideration of an optical proximity effect among the 0° phase transparent layers 27a and 27c and the 180° phase transparent layer 27b, as well as the gate 15 overlying the active region pattern 13.

Hereinafter the pattern including a predetermined portion of the field poly 17 and the gate 15 is referred to as a gate pattern, and the poly pattern formed outside the region on which such a gate pattern is formed will be referred to as a field poly pattern. In other words, a field poly pattern 45 and gate patterns 43a and 43b including the gate 15 having a reduced length are formed. Here, reference numeral 41 indicates an exposed region.

The trim mask 20 may be comprised of a halftone phase shift mask. FIGS. 2A and 2B are graphs each showing the exposure deviation with respect to depth of focus (DOF) in the cases of using a conventional chrome binary mask and a conventional phase shift mask, respectively, as the trim mask 20. In the case of using a chrome binary mask as a trim mask (refer to FIG. 2A), the common range of exposure deviation and the margin of focal depth between a dense gate pattern region and an isolate gate pattern region are larger than those in the case of using a phase shift mask as the trim mask 20 (refer to FIG. 2B). In other words, if the trim mask 20 is comprised of a chrome binary mask, it is possible to obtain a sufficient margin required in a process for forming a gate pattern having a reduced length. However, if the trim mask 20 is comprised of a chrome binary mask, the margin of focal depth in a field poly pattern is very small. Thus, if the focal depth only slightly increases, the field poly pattern and a gate pattern are disconnected.

If the trim mask 20 is comprised of a halftone phase shift mask, the margin of focal depth in a field poly pattern increases, however, as shown in FIG. 2B, the margin of focal depth in a gate pattern decreases. Thus, it is difficult to obtain a sufficient process margin.

In addition, if the trim mask 20 is comprised of a chrome binary mask, the length of a gate or a gate pattern may be reduced. However, as semiconductor chips become more compact, it is difficult to reliably reduce the length of a field poly pattern. On the other hand, if the trim mask 20 is comprised of a halftone phase shift mask, the length of a gate pattern cannot be reduced, but the length of a field poly pattern can be reduced. Thus, it is difficult to reliably reduce the size of a chip.

If the trim mask 20 is comprised of a halftone phase shift mask, the trim mask 20 must be optically corrected in consideration of the optical proximity effect of the trim mask 20 as well as the optical proximity effect of the shifter 26. Accordingly, it is difficult to form a mask having corrected optical proximity.

### SUMMARY OF THE INVENTION

To solve the above-described problems, it is a first feature of an embodiment of the present invention to provide a photomask including a trim mask, which is capable of obtaining a sufficient process margin for a gate pattern and a field poly pattern, and a method for manufacturing the same.

It is another feature of an embodiment of the present invention to provide a photomask including a trim mask, which is capable of reducing the size of a chip, and a method for manufacturing the same.

It is a further feature of an embodiment of the present invention to provide a photomask and a method for manufacturing the same which are capable of more easily performing optical proximity correction on a gate pattern.

Accordingly, there is provided a photomask including a shifter and a trim mask for blocking transmission of particular light passing through the shifter from reaching a wafer. Here, the trim mask includes a first part including a chrome mask and a second part including a phase shift mask.

The first part of the trim mask corresponds to a region on which a gate pattern including a gate of a chip and a predetermined portion of a field poly extending from the gate will be placed, and the second part of the trim mask corresponds to a region on which a field poly pattern comprised of the field poly, but not the first part, will be placed.

Preferably, the boundaries between the first and second parts at two opposite sides of the trim mask are aligned with two opposite edges of an imaginary layer, which corresponds to the two opposite sides of the trim mask and is introduced when designing the trim mask; however, it is also allowable that the boundaries between the first and second parts at one of two opposite sides of the trim mask are a predetermined distance away from one of two opposite edges of an imaginary layer, which corresponds to the two opposite sides of the trim mask and is introduced when designing the trim mask. Here, the predetermined distance is preferably no greater than the wavelength of light illuminated on the photomask. Specifically, in the case of using KrF as a light source, the predetermined distance is no greater than 2480 Å. In the case of using ArF as a light source, the predetermined distance is no greater than 1930 Å.

The other opposite edges of the trim mask are placed within corresponding edges of the imaginary layer.

In order to manufacture the trim mask, a substrate, which does not readily contract or expand due to heat, such as a quartz substrate, is prepared. A shift material layer, for example MoSi, and an opaque light blocking layer, for example, a chrome layer having the same size are sequentially formed on the substrate, and then a chrome layer pattern having a size smaller than the shift material layer is formed by patterning the chrome layer. In order to form the chrome layer pattern, a mask having a length smaller than the chrome layer is formed on the shift material layer and the chrome layer exposed by the mask are removed. According to another embodiment of the present invention, the step of forming the trim mask comprises sequentially forming a shift material layer and a chrome layer having a size smaller than the shift material layer on a substrate and patterning the shift material layer to form a patterned shift material layer that is larger than the chrome layer.

Accordingly, a chrome mask is formed of the chrome layer pattern where a gate pattern will be positioned, and a phase shift mask is formed of the shift material layer pattern where a poly pattern will be positioned.

These and other features of the present invention will be readily apparent to those of ordinary skill in the art upon review of the detailed description that follows.

### BRIEF DESCRIPTION OF THE DRAWINGS

The above features and advantages of the present invention will become more apparent by describing in detail preferred embodiments thereof with reference to the attached drawings in which:

FIG. 1 illustrates a view of a conventional method for forming a gate having a reduced length using a photomask including a shifter and a trim mask according to the prior art;

FIGS. 2A and 2B are graphs showing the exposure deviation with respect to depth of focus in the cases of using a conventional chrome binary mask and a conventional phase shift mask, respectively, as a trim mask according to the prior art;

FIG. 3 illustrates a plan view of a trim mask according to the present invention;

FIG. 4 is a diagram illustrating focal depth with respect to overlapped margins of a trim mask according to the present invention and an imaginary layer introduced when designing the trim mask;

FIGS. 5A through 5D illustrate cross-sectional views of a method for manufacturing a trim mask according to a first embodiment of the present invention, taken along the line I-I of FIG. 3; and

FIGS. 6A through 6C illustrate cross-sectional views of a method for manufacturing a trim mask according to a second embodiment of the present invention, taken along the line I-I of FIG. 3.

### DETAILED DESCRIPTION OF THE INVENTION

Korean Patent Application No. 01-28484, filed on May 23, 2001, and entitled: “Photomask and Method for Manufacturing the Same,” is incorporated by reference herein in its entirety.

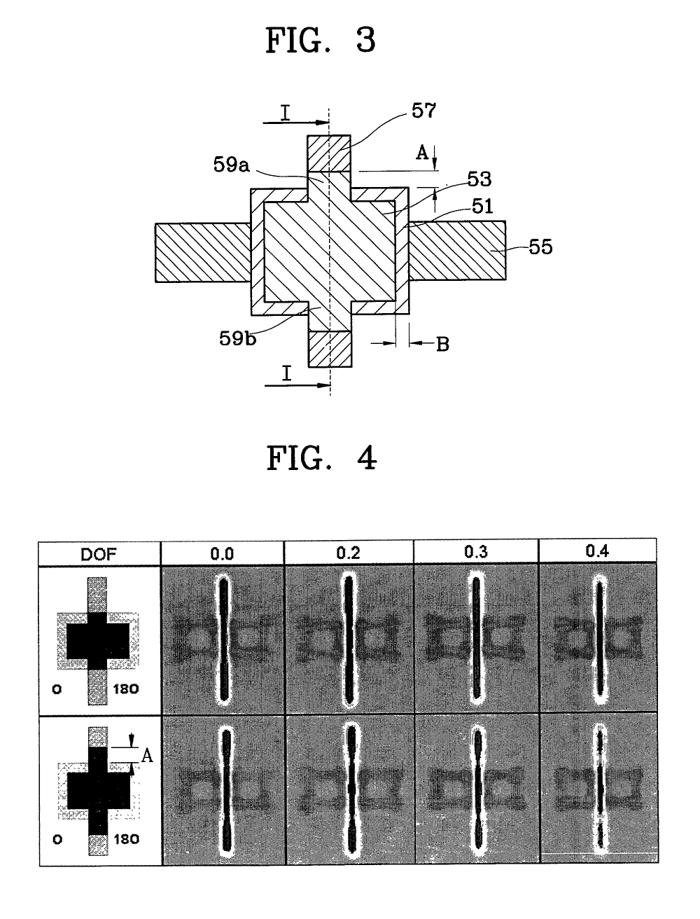

The present invention will now be described more fully with reference to FIGS. 3, 4, 5A through 5D, and 6A through 6C.

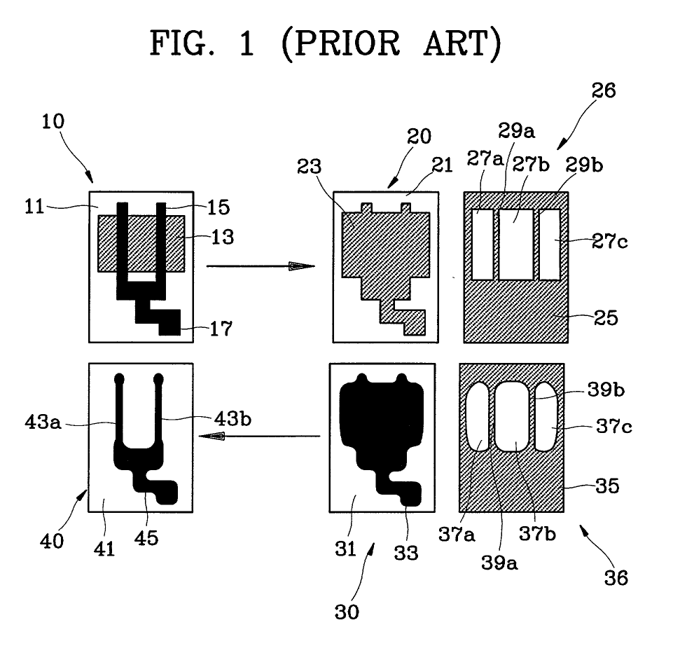

Referring to FIG. 3, a photomask includes a trim mask and a shifter (not shown). The trim mask includes a chrome mask 53 positioned at a region on which a gate pattern will be formed and a phase shift mask 57 positioned at a region on which a field poly pattern will be formed or positioned at other regions that will not be occupied by the gate pattern. Here, the gate pattern, as described with reference to FIG. 1, includes a gate, which is formed to overlie only an active region 55, and a predetermined portion of a field poly extending from the gate in consideration of the optical proximity effect of the shifter. The field poly pattern indicates a poly pattern formed at a predetermined region other than the region on which the gate pattern will be formed. Reference numeral 51 indicates an imaginary layer which has been introduced when designing the trim mask to divide the chrome mask 53 and the phase shift mask 57 and overlies the chrome mask 53 of the trim mask. There are protrusion portions 59a and 59b vertically extending from the chrome mask 53. The edges of the protrusion portions 59a and 59b and the upper edge of an imaginary layer 51 are a predetermined distance A apart. Preferably, the distance A is zero. If the distance A is merely in a range no greater than the wavelength of a light source, the spirit of the present invention may be realized. Since KrF and ArF, either of which may be used as a light source, have a wavelength of 2480 Å and 1930 Å, respectively, the distance A is preferably no greater than 2480 Å.

The left and right edges of the trim mask 53 and the left and right edges of the imaginary layer 51 are a predetermined distance B apart, respectively. If a mask manufacturing equipment for forming the trim mask 53 is ideal, in other words, if the mask manufacturing equipment is precisely aligned to a desired location at which mask patterns will be formed, a gap having the distance B between the left edge of the chrome mask 53 and the left edge of the imaginary layer 51, or between the right edge of the chrome mask 53 and the right edge of the imaginary layer 51, is not necessary.

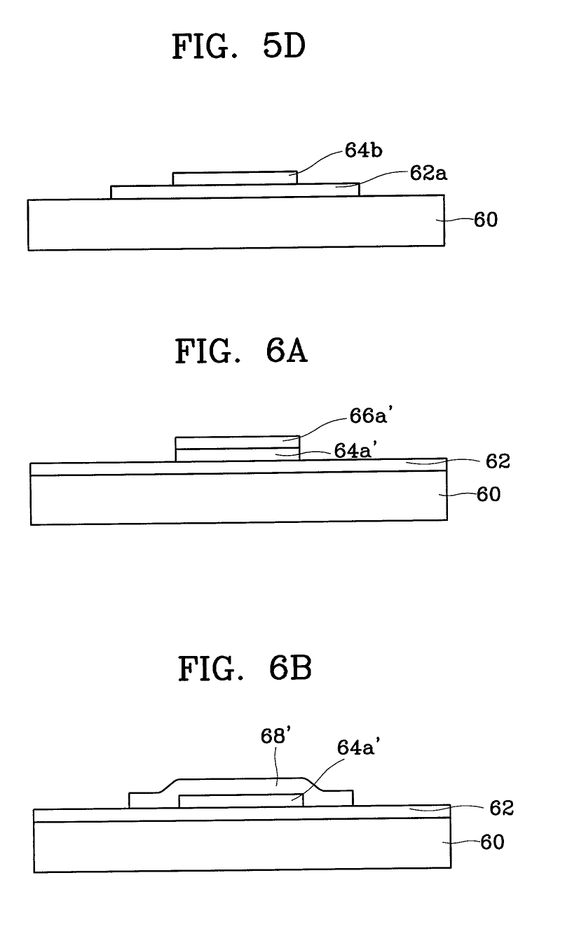

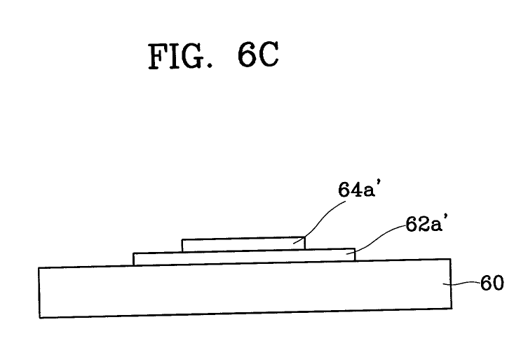

In the present invention, in order to form a trim mask, exposure is performed two times (refer to FIGS. 5A through 5D and 6A through 6C). In other words, the exposure of the present invention consists of a first exposure step for forming the chrome mask 53 of the trim mask and a second exposure step for forming the phase shift mask 57 of the trim mask. Thus, in order to obtain an overlapped margin between the chrome mask 53 and the phase shift mask 57 in the second exposure step, the gap having the distance B must be prepared between the left edge of the chrome mask 53 and the left edge of the imaginary layer 51 and between the right edge of the chrome mask 53 and the right edge of the imaginary layer 51. Therefore, the distance B may vary depending on the capability of mask exposure apparatus.

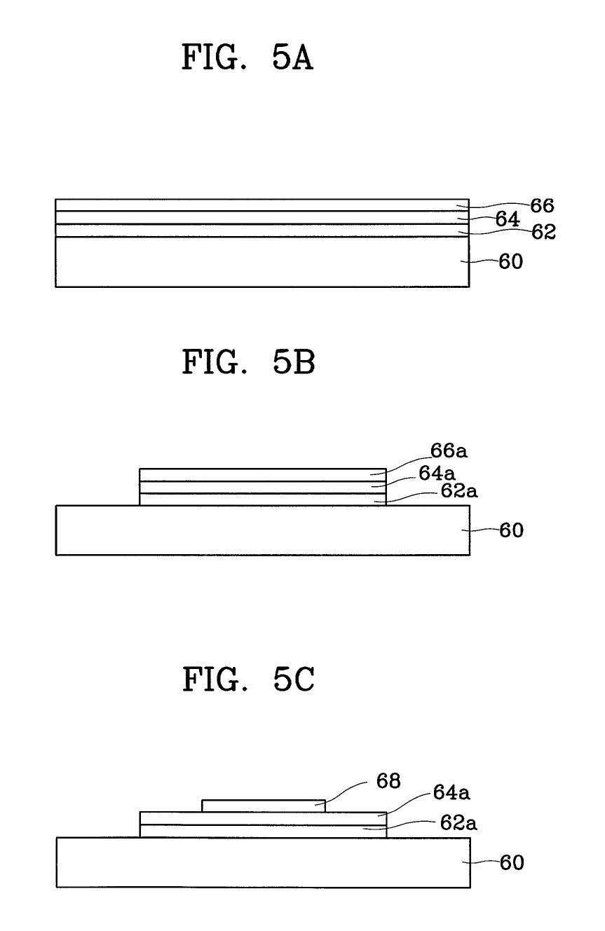

The distance A from the edge of each of the protrusion portions 59a and 59b of the chrome mask 53 of the trim mask to the top edge of the imaginary layer 51 will be described more fully with reference to FIG. 4. FIG. 4 shows variations in a pattern with respect to focal depth in a first case where A is 0 and a second case where A is greater than the wavelength of light illuminated on a photomask. Where A is 0, a gate and a field poly are not disconnected even though the focal depth gradually increases. However, where A is greater than the wavelength of light illuminated on the photomask, as the focal depth gradually increases, the connecting portion between a gate pattern and a field poly pattern becomes thin. In other words, portions of the gate pattern and the field poly pattern around the border between the chrome mask 53 and the phase shift mask 57 become thinner (or narrower). When the focal depth is 0.4, the gate pattern and the field poly pattern are disconnected. If A increases and accordingly, the chrome mask is placed at the region on which the field poly pattern is formed, the margin of focal depth in the field poly pattern is deteriorated. Therefore, in the present invention, a phase shift mask, instead of a chrome mask, is positioned on the field poly pattern region.

The upper/lower edges of the imaginary layer 51 were originally intended to be aligned with the edges of the upper/lower protrusions 59a and 59b, respectively, of the chrome mask 53. However, due to instability of an exposure apparatus during an exposure process, the upper/lower edges of the imaginary layer 51 may be isolated from the edges of the upper/lower protrusions 59a and 59b, respectively, of the chrome mask 53. If the distance A from the upper/lower edges of the imaginary layer 51 to the edges of the upper/lower protrusions 59a and 59b, respectively, of the chrome mask 53 is in the range of the wavelength (may be positive or negative) of light used, it is possible to obtain a sufficient margin required to form the gate pattern and the field poly pattern. Therefore, it becomes easier to manufacture a gate pattern or a gate having a reduced length.

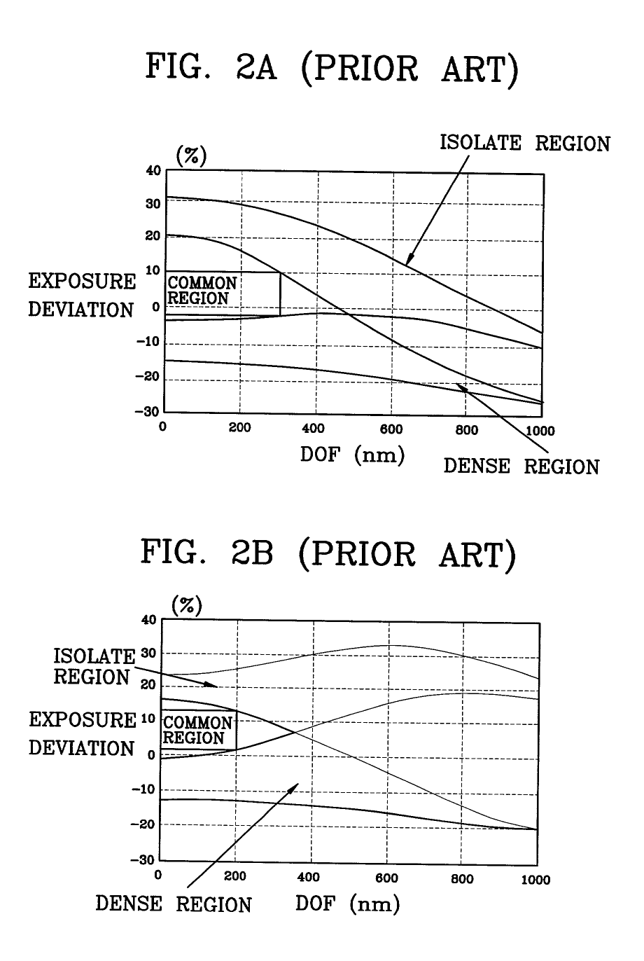

In sum, in the prior art, a trim mask is formed by installing a chrome mask at positions corresponding to a gate pattern region and an field poly pattern region. It is possible to reduce the length of a gate pattern or a gate using the trim mask comprised of a chrome mask; however, it is impossible to reduce the length of a field poly pattern. On the other hand, as described above, the trim mask of the present invention includes a chrome mask installed at a position corresponding to a gate pattern region and a phase shift mask installed at a field poly pattern region. Accordingly, as shown in FIG. 2A, the margin of focal depth in the gate pattern region can be obtained, and simultaneously, as shown in the upper boxes of FIG. 4, the margin of focal depth in the field poly pattern region can be obtained.

As a result, it is possible to reduce the length of a field poly pattern as well as the length of a gate pattern, and thus it is possible to reduce the size of a chip using the trim mask of the present invention.

In the trim mask of the present invention, since the phase shift mask does not occupy the gate pattern region, optical proximity correction for correcting an optical interference effect that may occur depending on whether or not a gate pattern or gate is dense may be performed in consideration of only a shifter. Therefore, the optical proximity correction may be more simplified and made easier than in the case of the prior art where only the phase shift mask is used as the trim mask.

Hereinafter, a method for manufacturing a trim mask will be described with reference to FIGS. 5A through 5D and 6A through 6C. FIGS. 5A through 5D illustrate a cross-sectional view taken along line I-I of FIG. 3, of a method for manufacturing a trim mask taking an overlapped margin in a second exposure step for forming a phase shift mask of the trim mask, i.e., the imaginary layer 51 of FIG. 3, into consideration. FIGS. 6A through 6C illustrate a cross-sectional view taken along line I-I of FIG. 3, of a method for manufacturing a trim mask without taking the imaginary layer 51 of FIG. 3 into consideration.

Referring to FIG. 5A, a MoSi layer 62, which is a halftone layer, a chrome layer 64, which is an opaque layer, and a photoresist layer 66, which will be used as a mask, are sequentially formed on a substrate 60 formed of a material, such as quartz, which does not readily expand or contract in spite of temperature or heat variations. Then, the photoresist layer 66 is patterned to have a predetermined length, thereby forming a photoresist layer pattern 66a. Referring to FIG. 5B, the chrome layer 64 and the MoSi layer 62 are patterned using the photoresist layer pattern 66a as a mask, thereby forming a chrome layer pattern 64a and a MoSi layer pattern 62a. Next, the photoresist pattern 66a is removed, and then another photoresist layer (not shown) is deposited on the entire surface of the substrate 60 on which the chrome layer pattern 64a is formed. Referring to FIG. 5C, the photoresist layer is patterned, thereby forming a photoresist layer pattern 68 having a size smaller than the chrome layer pattern 64a. Referring to FIG. 5D, the chrome layer pattern 64a is etched using the photoresist layer pattern 68 as a mask, thereby forming a chrome layer pattern 64b, which has been patterned twice. Then, the photoresist layer pattern 68 is removed, thereby completing a trim mask according to a first embodiment of the present invention.

Hereinafter, another method for manufacturing a trim mask according to the present invention will be described. Referring to FIG. 6A, the MoSi layer 62, which is a halftone layer, the chrome layer 64, which is an opaque layer, and a photoresist layer 66, which will be used as a mask, are sequentially formed on the substrate 60, as shown in FIG. 5A. Next, the photoresist layer 66 is patterned, and then only the chrome layer 64 is patterned using the patterned photoresist layer 66. In FIG. 6A, reference characters 66a′ and 64a′ refer to a patterned photoresist layer and the patterned chrome layer, respectively. Then, the patterned photoresist pattern 66a′ is removed and another photoresist layer is deposited on the entire surface of the substrate 60 including the chrome layer pattern 64a′. Referring to FIG. 6B, the photoresist layer is patterned, thereby forming a photoresist layer pattern 68′ which is larger than the chrome layer pattern 64a′. The edge of the photoresist layer pattern 68′ is aligned with the edge of the chrome mask 53 of FIG. 3. Next, referring to FIG. 6C, the MoSi layer 62 formed on the substrate 60 is patterned using the photoresist layer pattern 68′, thereby forming a patterned MoSi layer 62a′. Next, the photoresist layer pattern 68′ is removed, thereby completing a trim mask according to a second embodiment of the present invention.

The present invention has been described as being limited to a trim mask. However, it is quite clear to those skilled in the art that an optical proximity effect may be compensated for through serif correction, hammer head correction, jog correction, or scattering bar correction.

The trim mask according to the present invention includes a chrome mask installed at a position corresponding to a gate pattern region and a phase shift mask installed at a field poly pattern region. Accordingly, the margin of focal depth in the gate pattern region may be obtained, and simultaneously, the margin of focal depth in the field poly pattern region may be obtained. As a result, it is possible to reduce the length of a field poly pattern as well as the length of a gate pattern, and thus it is possible to reduce the size of a chip using the trim mask of the present invention. Moreover, it becomes easier to perform optical proximity correction on the gate pattern region.

Preferred embodiments of the present invention have been disclosed herein and, although specific terms are employed, they are used and are to be interpreted in a generic and descriptive sense only and not for purpose of limitation. Accordingly, it will be understood by those of ordinary skill in the art that various changes and modifications in form and detail may be made without departing from the spirit and scope of the present invention as set forth in the following claims.

What is claimed is:

1. A photomask comprising:
a shifter; and
a trim mask for blocking transmission of a particular light passing through the shifter from reaching a wafer, the trim mask including a first part having a chrome mask and a second part having a phase shift mask.

2. A photomask as claimed in claim 1, wherein the first part corresponds to a region on which a gate pattern including a gate of a chip and a predetermined portion of a field poly extending from the gate will be placed, and the second part corresponds to a region on which a field poly pattern comprised of the field poly, but not the first part, will be placed.

3. A photomask as claimed in claim 1, wherein boundaries between the first and second parts at two opposite sides of the trim mask are aligned with two opposite edges of an imaginary layer, which corresponds to two opposite sides of the trim mask and is introduced when designing the trim mask.

4. A photomask as claimed in claim 2, wherein boundaries between the first and second parts at two opposite sides of the trim mask are aligned with two opposite edges of an imaginary layer, which corresponds to two opposite sides of the trim mask and is introduced when designing the trim mask.

5. A photomask as claimed in claim 1, wherein boundaries between the first and second parts at one of two opposite sides of the trim mask are a predetermined distance away from one of two opposite edges of an imaginary layer, which corresponds to the two opposite sides of the trim mask and is introduced when designing the trim mask.

6. A photomask as claimed in claim 2, wherein boundaries between the first and second parts at one of two opposite sides of the trim mask are a predetermined distance away from one of two opposite edges of an imaginary layer, which corresponds to the two opposite sides of the trim mask and is introduced when designing the trim mask.

7. A photomask as claimed in claim 6, wherein the predetermined distance is no greater than the wavelength of light illuminated on the photomask.

8. A photomask as claimed in claim 6, wherein the predetermined distance is about 2480 Å.

9. A photomask as claimed in claim 1, wherein the other opposite edges of the trim mask are placed within corresponding edges of the imaginary layer.

10. A method for manufacturing a photomask comprising:
preparing a shifter; and
forming a trim mask for blocking transmission of a particular light passing through the shifter from reaching a wafer, the trim mask having a first part including a chrome mask and a second part including a phase shift mask.

11. The method as claimed in claim 10, wherein the first part corresponds to a region on which a gate pattern including a gate of a chip and a predetermined portion of a field poly extending from the gate will be placed, and the second part corresponds to a region on which a field poly pattern comprised of the field poly, but not the first part, will be placed.

12. A method as claimed in claim 11, wherein forming the trim mask comprises:
preparing a substrate;
sequentially forming a shift material layer and a chrome layer having the same size on the substrate; and
forming a chrome layer pattern having a size smaller than the shift material layer by patterning the chrome layer.

13. A method as claimed in claim 12, wherein forming the chrome layer pattern comprises:
forming a mask having a length smaller than the chrome layer on the shift material layer; and
removing the chrome layer exposed by the mask.

14. A method as claimed in claim 13, wherein the shift material layer is formed of MoSi.

15. A method as claimed in claim 13, wherein the mask is formed of photoresist.

16. A method as claimed in claim 12, wherein the substrate is formed of quartz.

17. A method as claimed in claim 11, wherein forming the trim mask comprises:
sequentially forming a shift material layer and a chrome layer having a size smaller than the shift material layer on a substrate; and
patterning the shift material layer to form a patterned shift material layer that is larger than the chrome layer.
